(19) United States
(12) Patent Application Publication
(10) Pub. No.: US 2012/0292676 A1
(43) Pub. Date: Nov. 22, 2012

(54) Novel Very Fast Optic Nonvolatile Memory with Alternative Carrier Lifetimes and Bandgap Energies, Optic Random Access, and Mirrored "Fly-back" Configurations

(76) Inventor: James Pan, Costa Mesa, CA (US)

(21) Appl. No.: 13/113,048

(22) Filed: May 21, 2011

(51) Int. Cl. H01L 31/113

(52) U.S. Cl. 257/290; 257/E31.085

(57) ABSTRACT

The present invention is for a fast optic nonvolatile memory cell (FONM) that operates with a speed >1000000 times faster than the commercially available FLASH memory. The information (or charges) can be entered into the FONM cell by switching on a built-in laser or LED (Light Emitting Diode). Excited by the lights, and driven by electric fields, the regions of low carrier lifetimes thermally generate excess electrons or positive charges to fill the storage gaps or interfaces. To detect the stored information, two BJTs (Bipolar Junction Transistors) are arranged in a mirrored configuration—with alternative regions of high or low carrier lifetimes and bandgap energies. By comparing the BJT “fly-back” characteristics a voltage difference can be detected as a signal of whether the information is stored or not stored.

### FIELD OF THE INVENTION

The present invention relates generally to memory devices, and more particularly, to high-speed much faster flash memory devices.

### BACKGROUND OF THE INVENTION

Flash memory is a type of electronic memory media that can be rewritten and hold its content without power. Unlike dynamic random access memory (DRAM) and static random access memory (SRAM), which are fast memories but the data are lost once the power is turned off; Flash memory can retain the data without an external power supply. The disadvantage of the commercially available Flash is the low speed compared to DRAM and SRAM. This drawback is the reason why Flash memory is not in use in personal computers. (Flash is used as an external memory, but not installed or built inside the computers as DRAM or SRAM.)

Conventional flash memory is very slow, because the stored information is deep inside an insulator or in between two insulators—very difficult and time consuming to retrieve the information.

The reason why DRAM and SRAM are volatile (data lost when power is off) is that extra charges disappear quickly in silicon (or other semiconductors), through a naturally occurring process called “thermal recombination”, if there is no external power supply. Thermal generation and recombination are naturally occurring processes that bring the silicon back to its thermal equilibrium condition without depletion of charges or extra charges. In a Flash memory, charges are stored inside dielectrics, or insulars (which are not semiconductors), so the charges are not affected by thermal recombination. This is the reason why Flash is nonvolatile. But it is slow to retrieve data because it takes a relatively long time for charges to “tunnel through” the dielectrics. DRAM and SRAM are faster because the stored charges, sustained by external power supply to compensate the thermal recombination, are located inside of silicon (a semiconductor). As long as charges are in the silicon they move very fast and the speed of the volatile memories can be very high, but they are volatile.

If the charges are stored inside silicon and sustained by an external power supply, the memory is fast but volatile. If the charges are stored inside dielectrics, no power supply is necessary to keep the charges, but the memory is very slow. To achieve high speed, nonvolatile memories, it is possible to store changes in a specially design charge storage device, in the interfaces, such as interfaces in between an p-type doped silicon and a n-type doped silicon, or interfaces in between silicon and silicon dioxide (which is an insulator or dielectric material). If the charges are stored in such charge storage devices in these interfaces, they are not affected by thermal recombination, which only occurs inside of silicon, so the charges can be kept without external power supply. It takes a very short time to retrieve the interfacial charges, because unlike Flash, the charges are not deeply inside the dielectric, thus no need for time consuming dielectric tunneling processes. Potentially, we can make high speed nonvolatile memories for personal computers this way, by storing charges in the charge storage devices in the interfaces, instead of storing charges in the insulators (in the case of Flash) or in the silicon (in the case of DRAM and SRAM).

In this patent application we will describe a high speed nonvolatile memory, storing charges in the specially designed devices at the interfaces, and achieving high speed with optic techniques.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later.

The present invention provides a very fast flash memory cell design that can be 1000000 times faster than any conventional flash memories. Unlike commercially available Flash, where the information is stored deep inside dielectrics and time consuming to retrieve, the information or charges in the fast nonvolatile memory device are stored in a special charge storage device at the interface or cavity or gap between the insulator and the semiconductor, or in between two semiconductors.

The fast nonvolatile memory cell stores one bit in a charge storage device in the interfacial cavity described in the previous paragraph. The bit can be programmed by turning on a laser or a light-emitting device. The bit can be read with a “fly-back” technique which will be described in the “DETAILED DESCRIPTION” section of this patent application. The bit can be erased by forcing a current through the device.

To the accomplishment of the foregoing and related ends, the invention comprises the features hereinafter fully described and particularly pointed out in the claims. The following description and the annexed drawings set forth in detail certain illustrative aspects and implementations of the invention. These are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1A is a cross sectional view illustrating a fast nonvolatile memory cell in accordance with an aspect of the present invention.

FIG. 1B shows two devices in parallel—Device 1 and Device 2. 101 is the first section for Device 1. It is connected to the sensing circuits. It can be built with silicon (or any semiconductor) and gold (or any carrier lifetime killer) to reduce the carrier lifetime. 107 in Device 2 is similar to 101, but is built with silicon (or any semiconductor) and carbon (or any carrier lifetime enhancer) to increase the carrier lifetime.

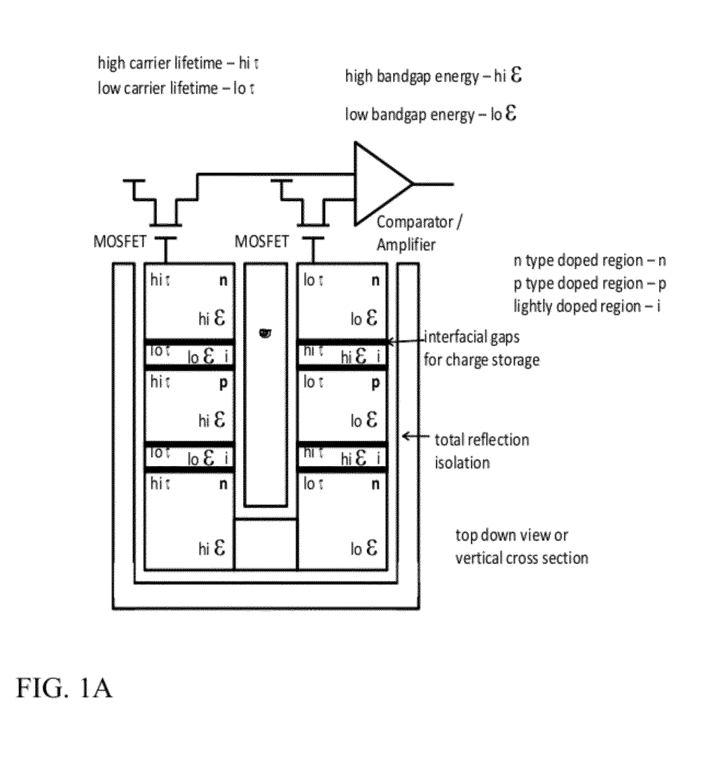

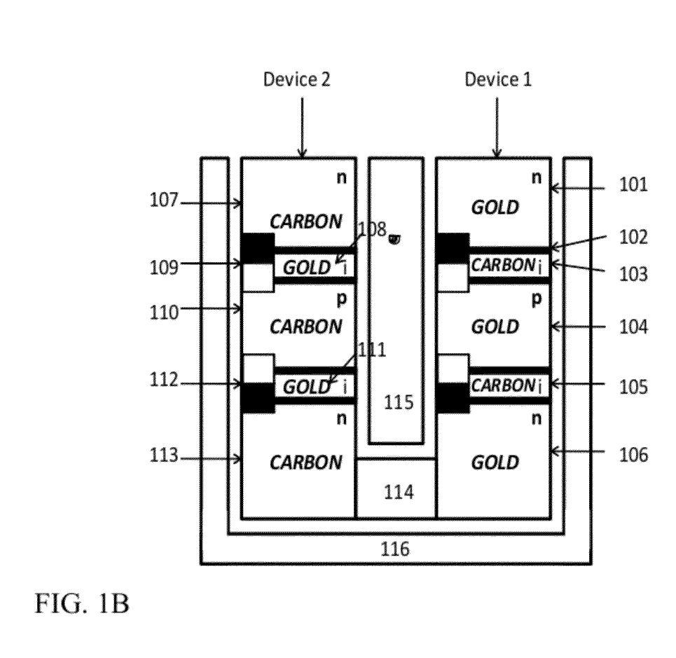

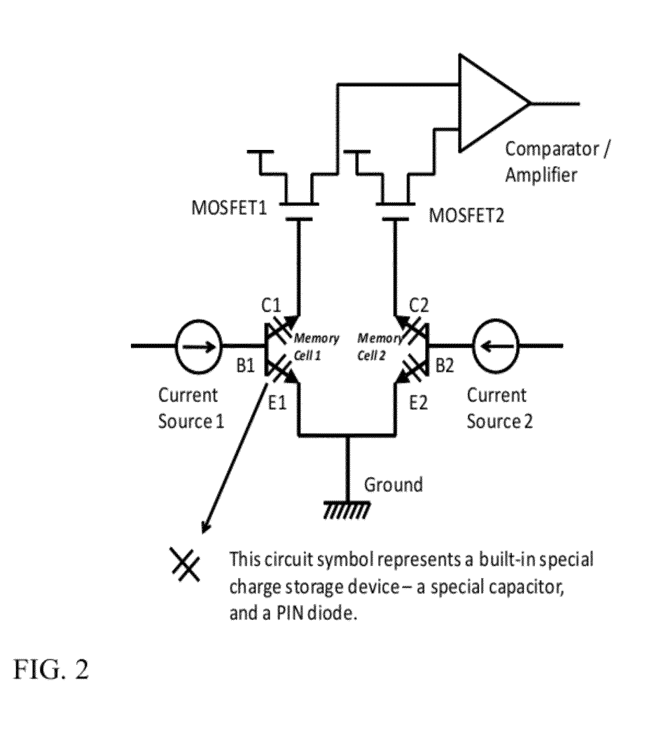

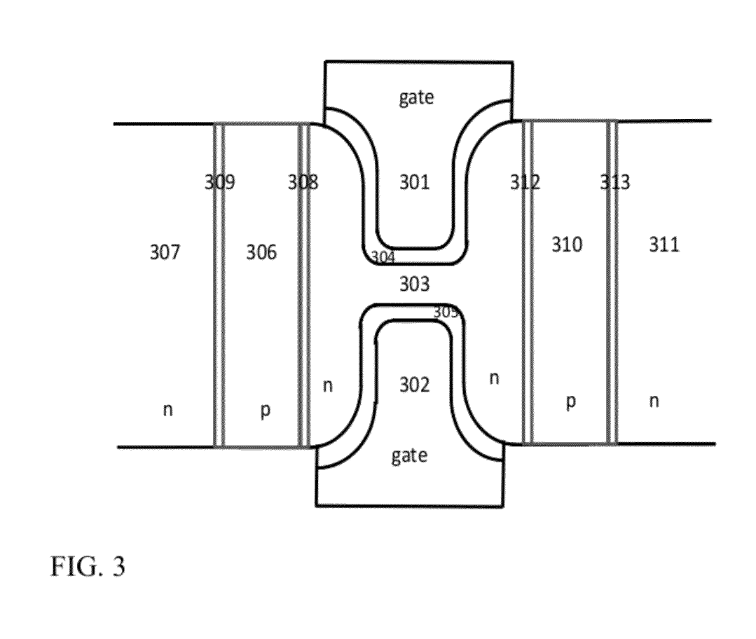

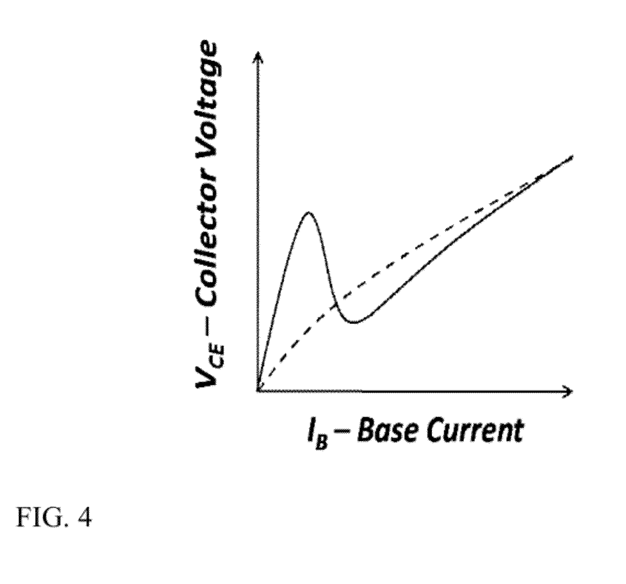

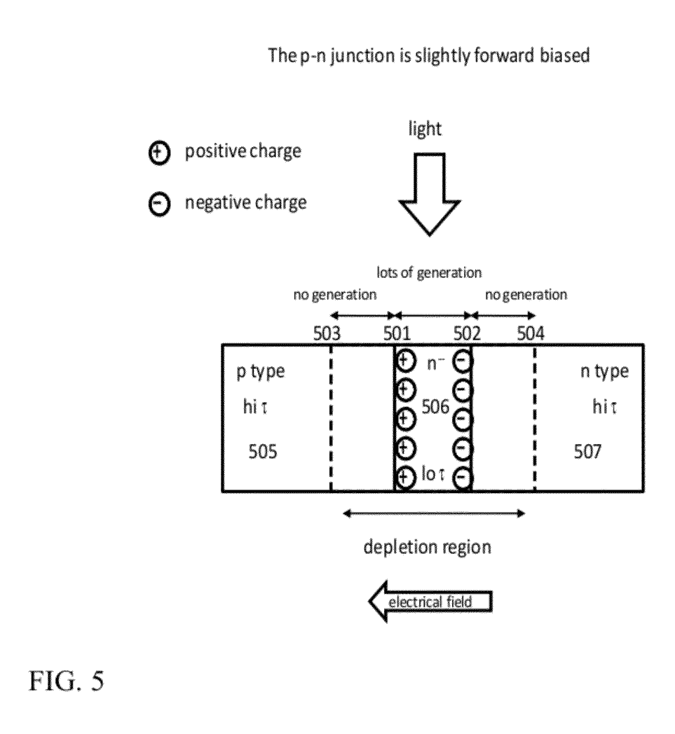

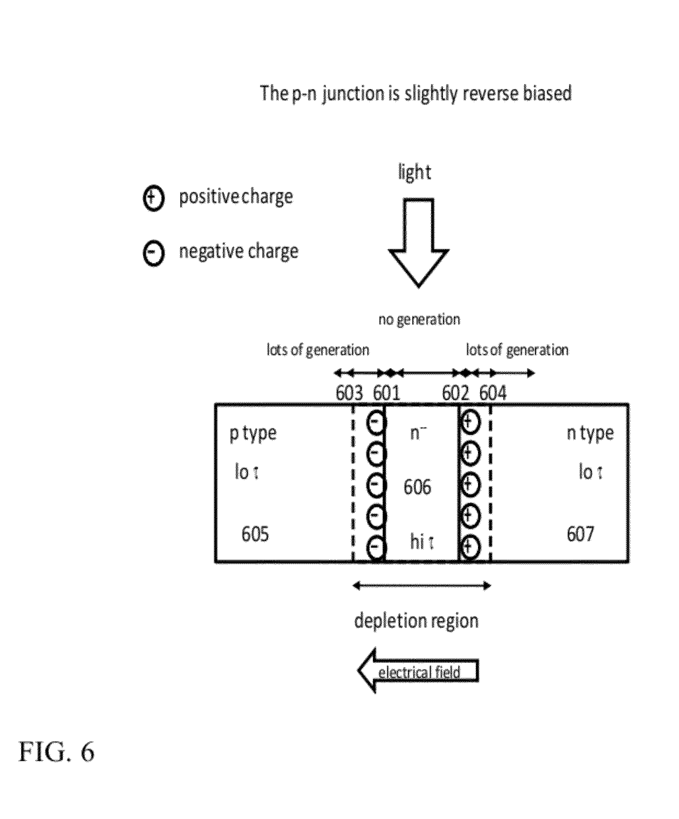

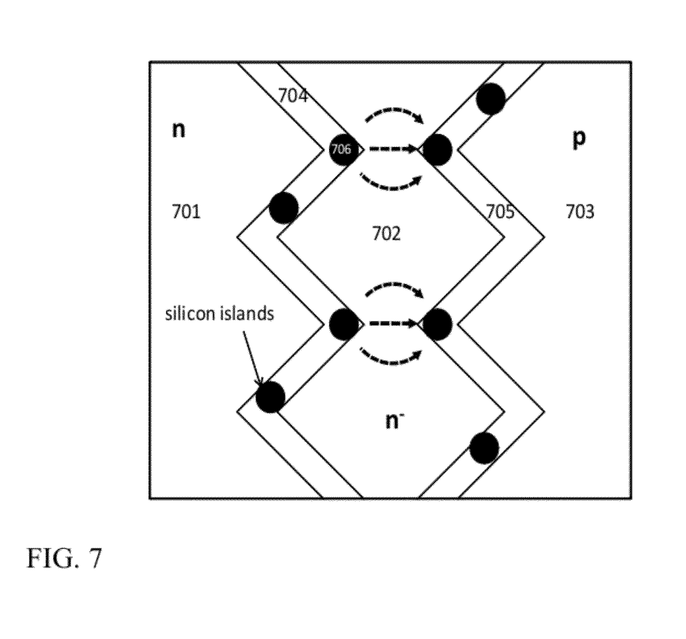

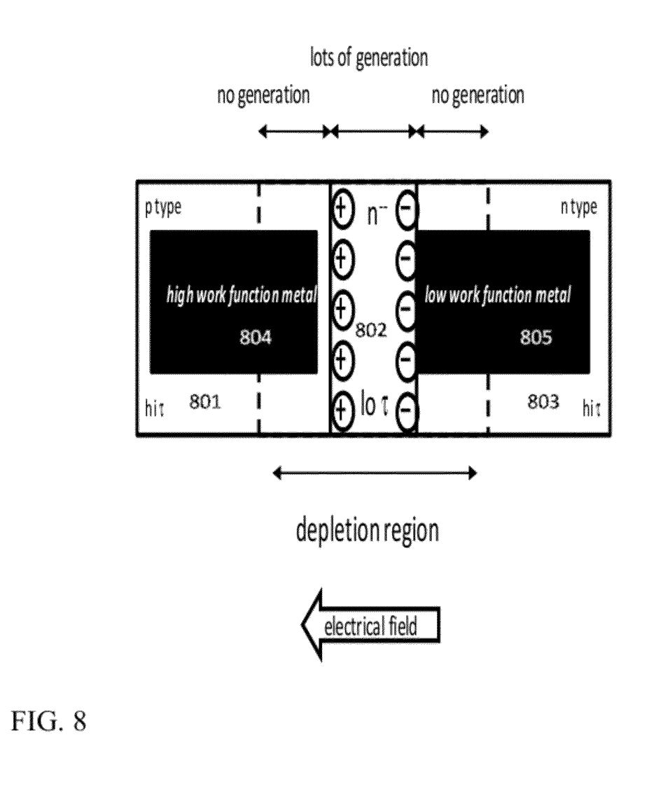

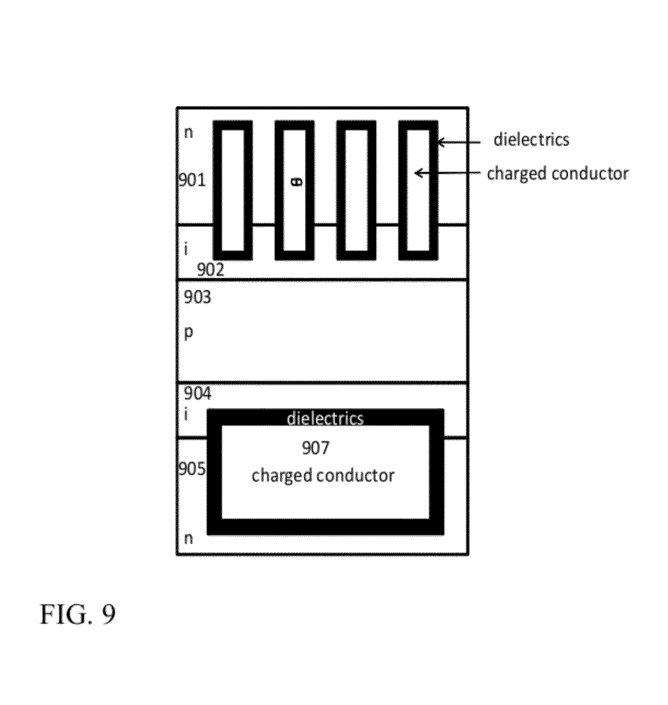

In FIG. 1B, 102 is the special charge storage device in the cavity or gap inside the semiconductors. Similar charge storage devices are located in between each section for both Device 1 and Device 2.

In FIG. 1B, 103 in Device 1 is the lightly doped region, where electric fields send carriers (electrons or positive charges) to the charge storage devices in the cavities or gaps. 108 is the counterpart of 103 in Device 2.

In FIG. 1B, 104 is in the middle of Device 1. It can be doped with gold to reduce the carrier lifetime. The counterpart of 104 is 110 in Device 2, but it is doped with carbon to increase the carrier lifetime.

In FIG. 1B, 105 is a lightly doped region similar to 103, doped with carbon. The counterpart is 111, doped with gold.

106 is the last section of Device 1 in FIG. 1B. It can be doped with gold to reduce the carrier lifetime. The counterpart is 113 in Device 2. It can be doped with carbon to increase the carrier lifetime.

106 and 113 are connected with 114, which can be a heavily doped semiconductor or a conductor.

109 and 112 are two (or multiple-section) p-n junction diodes or two (or multiple) sections of semiconductors or metals, doped with different impurities, to enhance the “fly-back” effects (fly-back enhancer). When the junction is reverse biased (electrical potential of an n-type region is higher than the p-type region), the enhancer produces no effect. When the junction is forward biased (electrical potential of an n-type region is lower than the p-type region), the enhancer produces a large current to enhance the fly-back. The same technique can be implemented in Device 1.

FIG. 2 describes the circuit of the memory cell. Memory cell 1 and memory cell 2 are in parallel. Each memory cell comprises a bipolar junction transistor (BJT), two built-in P-I-N diodes (p type, intrinsic or lightly doped, n type regions), and two special charge storage devices. C1 and C2 are the collectors of the BJTs. B1 and B2 are the bases of the BJTs. E1 and E2 are the emitters of the BJTs. The gates of the MOSFET1 and MOSFET2 are connected to the collectors. Current sources are connected to the bases of the BJTs. A comparator or amplifier is connected to the output of the MOSFETs to detect the difference of the output signals.

FIG. 3 shows a memory cell with the two branches or “arms” in the U shape structure (FIG. 1), 180 degrees to each other. MOS (Metal Oxide Semiconductor) devices are integrated in the 303 section. Charges can be stored in between 304 and 303, and in between 305 and 303. These charges can change the “fly-back” characteristics. 301 and 302 are the gate electrodes (metals, heavily doped polysilicon or conductors). 304 and 305 are dielectrics. 308, 309, 312, 313 are the charge storage devices in the interfacial cavities.

FIG. 4 shows the collector voltage vs. base current characteristics of the memory cell. The solid curve shows the “fly-back”, which can also happen to a bipolar junction transistor (BJT). The dashed curve shows no fly-back, due to the stored changes in the memory cell. The difference between the solid and dashed curves can be sensed by the circuit to determine whether the memory stores bit 1 or bit 0.

FIG. 5 describes how the memory cell works. A PIN diode is shown, with 3 regions—p type, intrinsic or lightly doped n-type, n type regions. The solid lines (501 and 502) show where the charge storage devices are located in the p type (505)/lightly dope n-type (506)/n type (507) structure. The dashed lines (503 and 504) show the boundary of the “depletion regions”, where free charges are absent due to the electric fields. When there are charges in 501 and 502, due to the low carrier lifetime (hence high thermal generation rate) in 506 (low t) after being exposed to laser lights, the fly-back characteristics (which is the output signal) can be changed.

FIG. 6 shows a PIN diode which is similar to FIG. 5, except that the low t and high t regions are reversed. 601 and 602 represent the charge storage devices in the interface. When there are charges in 601 and 602, due to the low carrier lifetime (hence high thermal generation rate) in 605 and 607 (low t) after being exposed to laser lights, the fly-back characteristics (which is the output signal) can be changed. Please notice the polarity of the stored charges is reversed compared to FIG. 5. The effect of the different polarities of the stored charges can have different effects on the fly-back characteristics.

FIG. 7 shows the charge storage device at the interface (cavity) in between the semiconductor regions for charge storage. 701 is n type. 702 is lightly doped n or p type. 703 is p type. 704 and 705 are the gaps or cavities in rugged or jigsaw patterns to enhance charge storage and local strong electric fields. There are silicon dots or polysilicon grains or implanted atoms (706) inside the cavities to modulate local electric fields and charge storage.

FIG. 8 illustrates a cross section of the p-n junction of the memory cell. 804 and 805 are metals inserted in 801 (p type), 802 (lightly dope n or p type), 803 (n type) regions. The metal can be of different work functions (work function is defined as the electric potential of a metal relative to the “vacuum”: a far-away place where there is no electric field as a reference point).

FIG. 9 shows a cross section of the p-n structure in the memory cell. Charged conductor islands (906 and 907), surrounded by insulators, can be inserted in the p type or n type regions to modulate the electric potential.

### DETAILED DESCRIPTION OF THE PATENT

The present invention will now be described with respect to the accompanying drawings in which like numbered elements represent like parts. The figures provided herewith and the accompanying descriptions of the figures are merely provided for illustrative purposes. One of ordinary skill in the art should realize, based on the instant description, other implementations and methods for fabricating the devices and structures illustrated in the figures and in the following description.

A PIN diode includes 3 regions: p type, lightly doped n or p type (also called “intrinsic”), n type regions. The intrinsic region is usually depleted, which means few charges are in this region. Due to the lack of charges, there is electric field in the intrinsic region and the depleted regions inside of the p and n type regions. When exposed to high-frequency lights, electrons or holes (positive charges) are generated by the light and carried away by the electric field in the intrinsic region and other depleted regions.

A bipolar junction transistor (BJT) is a device with 3 regions—n type, p type, and n type—called NPN BJT. If the 3 regions are p type, n type, p type—it is called PNP BJT. The 3 regions are called emitter, base, and collector, respectively. When an electric current source is applied to the base, the BJT responds by sending an output voltage at the collector. The base current vs. collector voltage plot is shown in FIG. 4 (solid curve). This is called a “fly-back” curve, due to the local peak in the collector voltage. The fly-back may or may not happen, due to the p-n junction conditions before the base current source is applied. The dashed curve shows no fly-back. By charging the charge storage devices at the interfaces in between the p type and n type regions, we can decide whether the fly-back will happen or not.

Referring now to the drawings, FIG. 1 illustrates an exemplary fast nonvolatile memory cell. The memory cell comprises a U shape structure. There is a novel BJT with charge storage capacitors and PIN diodes in each branch of the U shape. The BJT consists of: 107 n type region (doped with carbon or other carrier lifetime enhancer), charge storage device, 108 intrinsic region (doped with gold or other lifetime killer), charge storage device, 110 p type region (doped with carbon), charge storage device, 1111 region (doped with gold), charge storage device, 113 n type region (doped with carbon). “i” stands for “near intrinsic” or lightly doped. Doping a silicon region with gold, or using narrow energy bandgap semiconductors, reduces the carrier lifetime. Low carrier lifetime increases the thermal generation of electrons and positive charges (also called “holes”). Doping a silicon region with carbon, or using a wide bandgap semiconductor, can increase the carrier lifetime. High carrier lifetime reduces the thermal generation rates of free electrons or holes. The BJT in the other branch of the U shape is constructed in the opposite way: 101 n type region (doped with gold), 102 charge storage device, 103 i region (doped with carbon), charge storage device, 104 p type region (doped with gold), charge storage device, 105 i region (doped with carbon), charge storage device, 106 n type region (doped with gold). 115 is a light emitting device (laser or LED). 116 is a conductor for reflecting light. The gold and carbon can be replaced with other materials that can decrease or increase the carrier lifetime.

The top regions (101 and 107) are connected to the gates of the MOSFETs (Metal Oxide Silicon Field Effect Transistor). The outputs of the MOSFETs are sent to a comparator. If there is fly-back in Device 1, and there is no fly-back in Device 2, one of the MOSFETs (the one connected to Device 1) will be turned on and send a signal to the comparator. The other MOSFET (connected to Device 2) will be off and send no output signal. This difference can be detected by the comparator. FIG. 2 shows the circuit.

In FIG. 3, MOS (Metal Oxide Semiconductor) structures are built in a U shape in one of the regions of the memory cell. When charges are stored at the interface in between the oxide (304 and 305) and semiconductor (303), the electric potential distribution in 303 is changed, causing a change in the fly-back characteristics.

FIG. 5 shows a p type (505), charge storage device (501), i type (506), charge storage device (502), n type junction (507), and describes how the memory cell functions. 503 and 504 shows the depletion edges. There is no free carrier in between 503 and 504. This depletion region naturally occurs when the p type and n type regions are in contact. The width of the depletion can be adjusted with external voltage supply. There is electric field inside the depletion region. When light is turned on, many charges are generated in 506 due to the low carrier lifetime. At the same time, few carriers are generated in 505 and 507, due to the high carrier lifetime. As the result, positive charges or holes are trapped in 501, and negative charges or electrons are trapped in 502, forming an internal electric field. The fly-back characteristics can be affected by the charges in 501 and 502.

FIG. 6 shows a p type (605), charge storage device (601), i type (606), charge storage device (602), n type junction (607), and describes how the memory cell functions. The structure is similar to FIG. 5, but the low t (low carrier lifetime) is replaced by high t (high carrier lifetime), and vice versa. When light is turned on, few changes are generated in 606 due to the high carrier lifetime. At the same time, many carriers are generated in 605 and 607, due to the low carrier lifetime. As the result, positive charges or holes are trapped in 601, and negative charges or electrons are trapped in 602, forming an internal electric field. The fly-back characteristics can be affected by the charges in 601 and 602. The electric field in FIG. 6 is in the opposite direction compared to the electric field in FIG. 5, because the polarity of the stored charges (in 601, 602, 501, and 502) is reversed. This difference in the electric field direction causes different effects in the fly-back characteristics.

FIG. 7 shows a specially designed charge storage device for trapping charges. A cavity (704) is in between an n type region 701 and a lightly doped i-region 702. Another cavity (705) is in between 702 (i regions) and 703 (p type region). The rugged or jigsaw patterns are to enhance the local electric fields. There are silicon islands, grains, or other implanted or incorporated atoms (706) inside 704 and 705 to further modulate the electric fields and charge storage.

FIG. 8 shows a cross section of one of the PIN diodes. Metals (804 and 805) of different work functions are inserted in various regions (801 and 803) to modulate the electric potentials, which can affect the fly-back output signals from the memory cells.

FIG. 9 shows a cross section of one of the PIN diodes. Insulated metal islands (906 and 907) are inserted in various regions (901, 902, 903, 904, and 905) to modulate the electric potentials, which can affect the fly-back output signals from the memory cells.

1. A very fast optic nonvolatile memory cell comprises an “U” shape structure, and laser or other light emitting device in between the two branches in the U shape, with each branch in the U shape following the sequence of: an n type doped region, a charge storage region, a lightly doped region, a charge storage region, a p type doped region, a charge storage region, a lightly doped region, a charge storage region, and an n type doped region, or as the following reversed sequence of: an p type doped region, a charge storage region, a lightly doped region, a charge storage region, a n type doped region, a charge storage region, a lightly doped region, a charge storage region, and an p type doped region.

2. The memory cell of claim 1, wherein gold (or other carrier lifetime killers) is fabricated in the n type and p type doped regions (for low carrier lifetime), and carbon (or other carrier lifetime enhancers) is fabricated in the lightly doped regions (for high carrier lifetime), and the parallel structure is mirrored but “reversed”-carbon is fabricated into the n type and p type doped regions, and gold is fabricated into the lightly doped regions.

3. The memory cell of claim 1 and claim 2, wherein the bandgap energies for the n type and p type doped regions are very high, and the bandgap energies for the lightly doped regions are very low, and the parallel structure is mirrored but “reversed”: the bandgap energies for the n type and p type doped regions are very low, and the bandgap energies for the lightly doped regions are very high.

4. A circuit representing the memory cell of claim 1-3, wherein the two branches in the memory cell are in parallel, with one current source connected to each of the central regions in the middle of the structure, in order to generate a voltage pulse in one end (top section) of the parallel devices, and the ends (top sections) of the parallel structures are attached to the gates of MOSFETs (metal-oxide-semiconductor field effect transistor), and the output signals from the MOSFETs are sent to a comparator, and a light emitting device is fabricated on top of or beside or in between the parallel memory cell branches, in order to generate charges in the memory cell.

5. The memory cell of claim 1, wherein the two branches or arms in the U shape is 180 or various degrees to each other, and the section connecting the two branches is sandwiched by the “double U shapes”—each covered by an MOS (metal-oxide-semiconductor) or other types of capacitors, with charge storage regions in between the oxide and the semiconductor.

6. The memory cell of claim 1, wherein the charge storage devices include rugged or jigsaw patterns forming the interfacial cavity, with many silicon islands, grains, or other implanted atoms in the cavity to enhance local electrical fields and charge storage.

7. The memory cell of claim 1, wherein metal regions of different work functions are inserted in p and n doped regions to regular the electrical potentials.

8. The memory cell of claim 1, wherein equal potential islands (consisting of metals enclosed by dielectrics) are inserted in the p type doped regions, lightly doped regions, and n type doped regions to modulate the electrical potentials.

9. The memory cell of claim 1, wherein a two- or multiple-section device (which can be one or multiple p-type sections and one or multiple n-type sections, or one or multiple metal sections and one or multiple semiconductor sections) is inserted in between the p-type and n-type regions to improve the output signals.

10. The memory cell of claim 1, wherein metals or conductors enclose the memory cell, to ensure light signals do not interfere with other nearby memory cells.
